(19) United States
(12) Patent Application Publication
(10) Pub. No.: US 2005/0161812 A1
(43) Pub. Date: Jul. 28, 2005

(54) WAFER-LEVEL PACKAGE STRUCTURE

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Jau-Shou Chen, Hsinchu Hsien (TW); Ching-Huei Su, Kaohsiung (TW); Chao-Fu Weng, Tainan (TW); Yung-Chi Lee, Kaohsiung (TW); Yu-Chen Chou, Kaohsiung (TW); Tsung-Hua Wu, Kaohsiung Hsien (TW); Su Tao, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,744

(22) Filed: Apr. 14, 2005

Related U.S. Application Data
(63) Continuation-in-part of application No. 10/248,114, filed on Dec. 19, 2002.

(30) Foreign Application Priority Data
Feb. 26, 2002 (TW) 91103381

(51) Int. Cl. H01L 23/48

(52) U.S. Cl. 257/737; 257/778

(57) ABSTRACT

A wafer-level package structure, applicable to a flip-chip type arrangement on a carrier having a plurality of contact points is described. This wafer-level package structure comprises a chip having a protective layer and a plurality of bonding pads and a conductive layer. The conductive layer is arranged on the bonding pads of the chip as contact points. The wafer-level package structure can further include a heat sink to enhance the heat dissipation ability of the package structure.

### CROSS-REFERENCE TO RELATED APPLICATION

This application is a continuation-in-part of a prior application Ser. No. 10/248,114, filed Dec. 19, 2002. All disclosure of this application is incorporated herein by reference. The prior application Ser. No. 10/248,114 claims the priority benefit of Taiwan application serial no. 91103381, filed on Feb. 26, 2002.

### BACKGROUNDING OF THE INVENTION

1. Field of Invention

The present invention relates to a wafer-level package structure. More particularly, the present invention relates to a wafer-level package structure that can replace the bump chip carrier (BCC) and the quad flat nonleaded (QFN) type of wafer-level package structure.

2. Description of Related Art

In today's information age, the market for multi-media applications is rapidly expanding. The packaging technique for integrated circuits thereby needs to be improved in accordance to the developing trends of electronic devices, such as, digitization, networking, local networking and user friendliness. In order to accommodate the above demands, electronic devices must maintain high operating speed and must be multifunctional, highly integrated, light weight and low cost. Therefore, the packaging technique for integrated circuits must also develop along the direction of further miniaturization and higher integration. Generally speaking, packaging products can be divided into the pin through hole (PTH) type and the surface mount device (SMD). The pin-through-hole type of packaging basically comprises pins of the device inserting into holes of the circuit board for electrical connection. The pin through hole type of packaging product is the best representative for the dual in-line package (DUP). The surface mount device, however, is directly arranged on a carrier. The contact point of the carrier and the lead of the package are electrically connected through a tin paste. As a result, the package can be easily fixed to the carrier.

Referring to FIGS. 1A and 1B, FIGS. 1A and 1B are schematic diagrams illustrating the cross-sectional views of a conventional bump chip carrier package structure. As shown in FIG. 1A, a conventional bump chip carrier package structure comprises a chip 100, a thermal conductive adhesive 104, a plurality of bonding wires 106, a plurality of terminals 108 and an encapsulant 110. The chip 100 comprises a plurality of bonding pads 102, and the chip 100 is configured on the thermal conductive adhesive 104. The bonding pads 102 on the chip 100 are electrically connected to the terminals 108 through the bonding wires 106. The encapsulant 110 is used to encapsulate the chip 100 and the bonding wires 106. Further, the thermal conductive adhesive 104 is exposed by the encapsulant 110 to enhance thermal dissipation. The terminals 108 are also exposed to the outside of the encapsulant 110 such that the chip 100 can be electrically connected to other carrier.

Referring to FIG. 1B, another type of bump chip carrier package is formed with a chip 100, a thermal conductive adhesive 104, a heat sink 114, a plurality of bonding wires 106 and 112, a plurality of terminals 108 and an encapsulant 110. The chip comprises a plurality of bonding pads 102. Further, the chip 100 is configured on the heat sink 114 with the thermal conductive adhesive 104. The bonding pads 102 on the chip 100 are electrically connected to the terminals 108 through the bonding wires 106. The bonding pads 102 are also electrically connected to the heat sink 114 through the bonding wires 112. The encapsulant 110 is used to encapsulate the chip 100, the thermal conductive adhesive 104 and the bonding wires 106 & 112. Further, the heat sink 114 is exposed to the outside of the encapsulant 110 in order for the chip 100 to be electrically connected to other carriers through the terminals 108.

Referring to FIG. 2, FIG. 2 is a schematic diagram illustrating a cross-sectional view of a conventional quad flat nonleaded package structure. The quad flat nonleaded package structure is a leadframe based CSP (Chip Scale Package) constructed on a lead frame. The quad flat nonleaded package is constructed on a lead frame, wherein the lead frame comprises a die pad 214 and a plurality of leads 208. The chip 200 is configured on the die pad 214 with a thermal conductive adhesive 204. The chip 200 comprises a plurality of bonding pads 202 thereon, wherein the bonding pads 202 are electrically connected to the leads 208 through the bonding wires 206. The bonding pads 202 can also be electrically connected to the die pad 214 through the bonding wires 212. The encapsulant 210 is used to encapsulate the chip 200, the thermal conductive adhesive 204 and the bonding wires 206, 212. Further, the die pad 214 is exposed to the outside of the encapsulant 210 to enhance the thermal dissipation of the package. The leads 208 are also exposed to the outside of the encapsulant 210 to allow the chip 200 to electrically connected with other carrier.

In a conventional BCC, chemical etching must be relied upon to expose the terminals, which greatly complicates the manufacturing process.

According to the prior art, wire bonding and molding must be performed regardless the packaging is a BCC type or a QFN type of structure. Therefore, the entire packaging process would become complicated.

Further, in the conventional BCC package or the QFN package, both bonding wires and encapsulant would affect the size and the weight of the entire package.

### SUMMARY OF THE INVENTION

Accordingly, the present invention provides a small-sized, light-weighted and easy manufactured wafer-level package structure. Further, the wafer-level package structure of the present invention is applicable and compatible with the package structures using the BCC package or the QFN package.

Accordingly, a wafer-level package structure is provided, which is applicable to a flip-chip arrangement on a carrier with multiple contact points (for example, a printed circuit board). The wafer-level package structure comprises mainly a chip and a conductive layer, wherein the chip comprises a plurality of bonding pads and a protective layer. The protective layer is used to protect the chip surface and to expose the surface of the bonding pad. The conductive layer is configured on the chip. The conductive layer is configured on, for example, the bonding pad, and is used as a contact point for bonding with a carrier. Further, a heat sink is configured at a region outside the bonding pads on the chip to increase the thermal dissipation capability of the package.

The chip used in wafer-level package of the present invention is, for example, a chip in which a re-distribution of bonding pads is already accomplished. The chip comprises a wiring and a dielectric layer. The aforementioned dielectric layer is disposed on the protective layer of the chip, wherein the dielectric layer comprises a plurality of openings. The wiring is distributed between the protective layer and the dielectric layer to fan out the bonding pads to appropriate locations, while the openings expose the wiring that is used to fan out the bond pads.

In accordance to the wafer-level package, wherein the bonding pads on the chip are, for example, peripherally distributed on the chip, while the heat sink is mounted, for example, inside the region enclosed by the bonding pads.

In the wafer-level package of the present invention, the material used to form the bonding pad on the chip includes, for example, copper, aluminum type of material. The material used to form the conductive layer (including the heat sink) includes, for example, aluminum/titanium tungsten alloy/nickel vanadium alloy/copper, chromium/nickel vanadium alloy/copper, aluminum/nickel vanadium alloy/copper and titanium/nickel vanadium alloy/copper type of material.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1B are schematic diagrams illustrating the cross-sectional views of a conventional bump chip carrier package.

FIG. 2 is a schematic diagram illustrating the cross-sectional view of a conventional quad flat nonleaded package.

FIG. 3 is a top view of a structure of a wafer-level package without a heat sink according to a first aspect of the present invention.

FIG. 4 is a cross-sectional view of the structure in FIG. 3 along the cutting line I-I.

FIG. 5 is a top view of a structure of a wafer-level package with a heat sink according to the first aspect of the present invention.

FIG. 6 a cross-sectional view of the structure in FIG. 5 along the cutting line II-II.

FIG. 7 is a top view of a structure of a wafer-level package without a heat sink according to a second aspect of the present invention.

FIG. 8 is a cross-sectional view of the structure in FIG. 7 along the cutting line

FIG. 9 is a top view of a structure of a wafer-level package with a heat sink according to the second aspect of the present invention.

FIG. 10 is a cross-section view of the structure in FIG. 9, along the cutting line IV-IV.

FIG. 11 is a cross-section view of the wafer-level package structure bonded to the carrier.

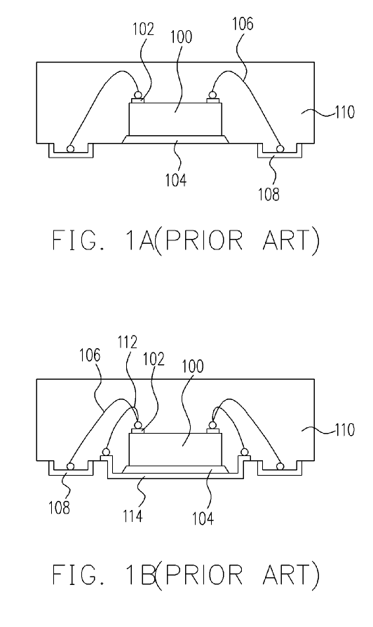

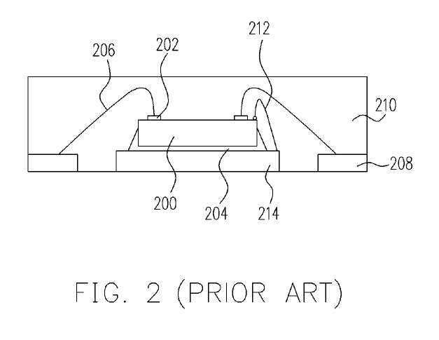

### DESCRIPTION OF THE PREFERRED EMBODIMENTS

First Aspect

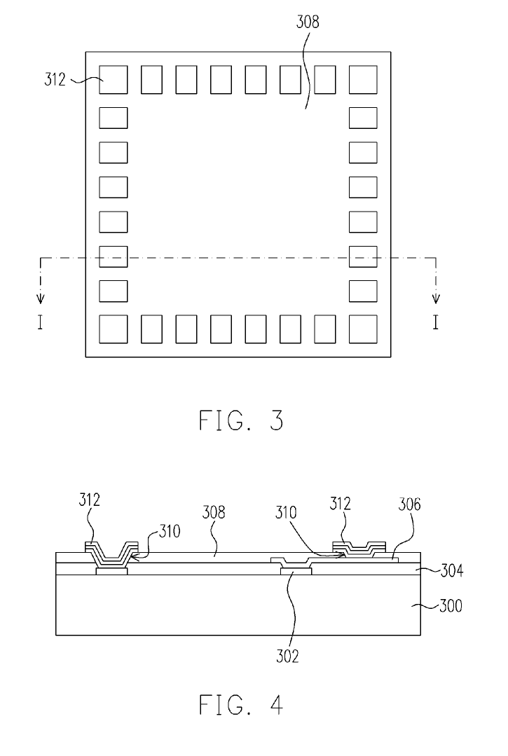

Referring to both FIG. 3 and FIG. 4, FIG. 3 is a top view of a structure of a wafer-level package without a heat sink according to the first aspect of the present invention, while FIG. 4 is a cross-sectional view of the structure in FIG. 3 along the cutting line I-I. The chip 300 comprises a plurality of bonding pads 302 and a protective layer 304. The protective layer 304 covers the active surface of the chip 300 and exposes the bonding pads 302. The arrangement of the bonding pads 302 can be varied according to the designs of the layout. The bonding pads 302 are formed with a material such as, copper or aluminum, etc., while the protective layer 304 is formed with, for example, a silicon oxide (SiOx) material or a silicon nitride (SiNx) material.

The chip 300 further comprises a wiring 306 and a dielectric layer 308 distributed thereon, wherein the dielectric layer 308, for example, comprises a plurality of openings 310 therein. For example, the openings 310 are distributed peripherally in the dielectric layer 308 on the chip 300. Moreover, the openings 310 expose the wiring 306 underneath the dielectric layer 308 or the bonding pad 302. The wiring 306 is distributed, for example, above parts of the bonding pads 302 and the protective layer 304, and is connected with the bonding pads 302 to fan-out to appropriate locations. The aforementioned dielectric layer 308 includes, for example, polyimide or benzene cyclobutene (BCB), etc., while the wiring (or circuit line) 306 is formed with, for example, copper. Moreover, a conductive layer 312 can be configured on the wiring 306 exposed by the opening 310 in the dielectric layer 308, wherein the conductive layer 312 is used as a contact point for the chip 300 with other carrier. The conductive layer 312 may also be disposed directly on the bonding pad 302. The conductive layer 312 includes, for example, aluminum/titanium tungsten alloy/nickel vanadium alloy/copper, chromium/nickel vanadium alloy/copper, aluminum/nickel vanadium alloy/copper and titanium/nickel vanadium alloy/copper type of material.

As shown in FIG. 3, since the openings 310 are peripherally distributed in the dielectric layer 308 on the chip 300, the conductive layer 312 exposed on the surface of the chip 300 is also peripherally distributed. Therefore, for those skilled in the art, it is understood that the opening 310 in the dielectric layer 308 and the conductive layer 312 can be gathered in the center, distributed in a grid array arrangement or other type of arrangement.

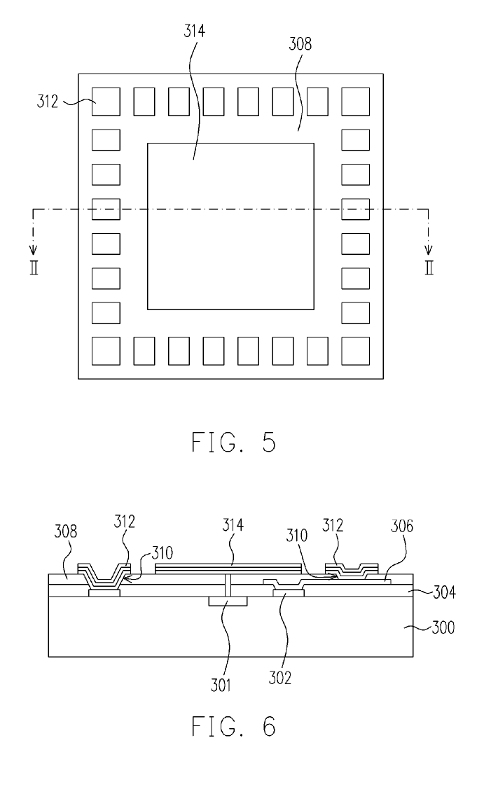

Referring to both FIG. 5 and FIG. 6, FIG. 5 is a top view of a structure of a wafer-level package with a heat sink according to the first aspect of the present invention, while FIG. 6 is a cross-sectional view of the structure in FIG. 5 along the cutting line II-II. The difference between the structures in FIGS. 5 & 6 and in FIGS. 3 & 4 is the arrangement of a heat sink.

According to the structure of the wafer-level package in FIGS. 5 and 6, a heat sink 314 is disposed on a central region of the dielectric layer 308 and the openings 310 are peripherally distributed in the dielectric layer 308 on the chip 300. Further, the conductive layer 312 is also peripherally distributed. The chip further comprises a ground plane 301 therein and the heat sink 314 can be electrically connected to the ground plane and thus be grounded. With the openings 310 and the conductive layer 312 being peripherally distributed, the heat sink 314 above the dielectric layer 308 is configured in the region enclosed by the conductive layer 312 to further increase the heat dissipation capability. The heat sink 314 and the conductive layer 312 can be formed from patterning the same material layer during the process. The material of the heat sink 314 includes, for example, aluminum/titanium tungsten alloy/nickel vanadium alloy/copper, chromium/nickel vanadium alloy/copper, aluminum/nickel vanadium alloy/copper and titanium/nickel vanadium alloy/copper type materials.

Second Aspect

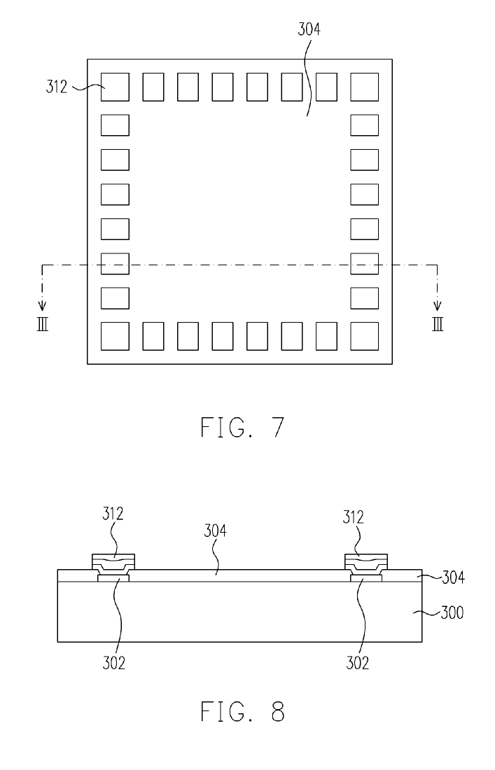

Referring to both FIGS. 7 and 8, FIG. 7 is a top view of a structure of a wafer-level package without a heat sink according to the second aspect of the present invention, while FIG. 8 is a cross-sectional view of a structure in FIG. 7 along the cutting line III-III. The chip 300 comprises a plurality of bonding pads 302 and a protective layer 304. The protective layer 304 covers the chip 300 and exposes the bonding pads 302, wherein the bonding pads 302 are peripherally distributed on the chip 300. The bonding pads 302 are, for example, copper or aluminum. The protective layer 304 is formed with, for example, silicon oxide (SiOx) or silicon nitride (SiNx) type of material.

Further, a conductive layer 312 is configured on the bonding pads 302 exposed on the surface of the chip 300. This conductive layer 312 is served as a contact point for the chip 300 with other carrier. The conductive layer 312 includes aluminum/titanium tungsten alloy/nickel vanadium alloy/copper, chromium/nickel vanadium alloy/copper, aluminum/nickel vanadium alloy/copper and titanium/nickel vanadium alloy/copper type of material.

As shown in FIG. 8, the bonding pads 302 are, for example, peripherally distributed on the chip 300. Therefore, the conductive layer 312 exposed on the surface of the chip 300 is also peripherally distributed. However, for those skilled in the art, it is understood that the bonding pad 302 and the conductive layer 312 can also be distributed in the center, in a grid array arrangement or other type of arrangement.

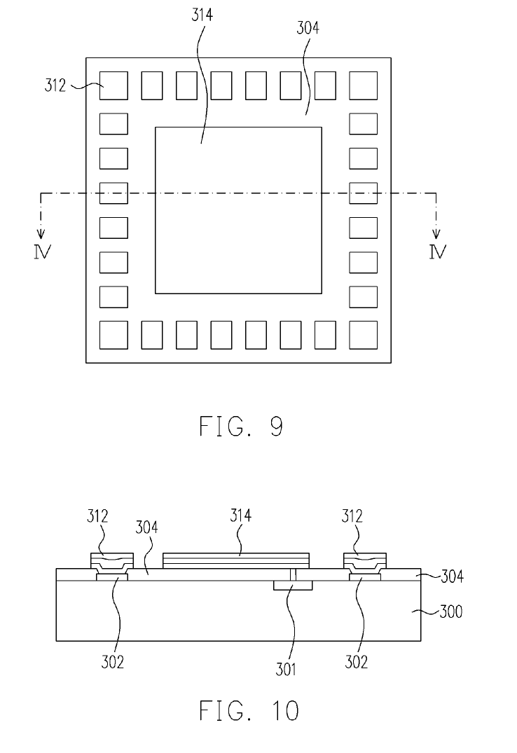

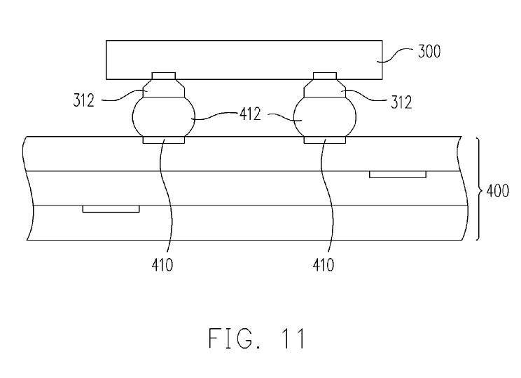

Referring to both FIG. 9 and FIG. 10, FIG. 9 is a top view of a structure of a wafer-level package with a heat sink according to the second aspect of the present invention, while FIG. 10 is a cross-section view of the structure in FIG. 9, along the cutting line IV-IV. The wafer-level structure in FIGS. 9 and 10 is similar to that in FIGS. 7 and 8. The only difference is the presence of a heat sink 314.

According to the wafer-level structure shown in FIGS. 9 & 10, a heat sink 314 is disposed on a central region of the dielectric layer 308 and the bonding pads 302, for example, are peripherally distributed on the chip 300, wherein the conductive layer 312 there above is also peripherally distributed. Because the bonding pads 302 or the conductive layer 312 is peripherally distributed, the heat sink 314 above the protective layer 304 is arranged inside the region enclosed by the bonding pads 302 and the conductive layer 312 to further enhance the thermal dissipation capability. The chip further comprises a ground plane 301 therein and the heat sink 314 can be electrically connected to the ground plane and thus be grounded.

Accordingly, the wafer-level package structure of the present invention does not require any lead frame. Therefore, the manufacturing process is simpler and more cost effective. Additionally, the wafer-level package structure of the present invention is less heavy compared to the BCC package or the QFN package.

Moreover, a plurality of solder bumps 412 can be formed on the conductive layer 312 of the above wafer-level package structures described in the present invention, as shown in FIG. 11. Through the bumps 412 on the conductive layer 312, the wafer-level package structure can be flipped and directly mounted to the contacts 410 of the carrier substrate 400, for example, the printed circuit board (PCB).

In accordance to the wafer-level package structure of the present invention, the bonding pads on the chip are connected to the contact point on the carrier directly with the conductive layer and the bumps. The signal transmission speed is thereby enhanced due to the shorter path. Furthermore, through the bumps, the wafer-level package structures of this invention can be bonded to the carrier in a flip-chip way.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A wafer-level package structure, which is applicable to a flip-chip type arrangement on a carrier, the carrier comprising a plurality of contact points and the wafer-level package structure comprising at least:
a chip, wherein the chip comprises a plurality of bonding pads and a protective layer, wherein the protective layer protects the chip and exposes a surface of the bonding pads;
a conductive layer, wherein the conductive layer is disposed on the bonding pads;
a heat sink disposed on the protective layer; and
a plurality of bumps disposed on the conductive layer and over the bonding pads, wherein the bumps are to be connected to the contact points of the carrier when the wafer-level package structure is mounted on the carrier.

2. The structure of claim 1, wherein the chip further comprises a ground plane and the heat sink is electrically connected to the ground plane.

3. The structure of claim 1, wherein the bonding pads are formed at a periphery of the chip.

4. The structure of claim 3, wherein the heat sink is formed inside a region enclosed by the bonding pads.

5. The structure of claim 1, wherein the bonding pads are formed with a material selected from the group consisting of copper and aluminum.

6. The structure of claim 1, wherein the conductive layer is formed with a material selected from the group consisting of aluminum/titanium tungsten alloy/nickel vanadium alloy/copper, chromium/nickel vanadium alloy/copper, aluminum/nickel vanadium alloy/copper and titanium/nickel vanadium alloy/copper.

7. The structure of claim 1, wherein the heat sink is formed with a material selected from the group consisting of aluminum/titanium tungsten alloy/nickel vanadium alloy/copper, chromium/nickel vanadium alloy/copper, aluminum/nickel vanadium alloy/copper and titanium/nickel vanadium alloy/copper.

8. The structure of claim 1, wherein the carrier includes a printed circuit board.

9. A wafer-level package structure, which is applicable to a flip-chip type arrangement on a carrier, the carrier comprising a plurality of contact points and the wafer-level package structure comprising at least:
a chip, wherein the chip comprises a plurality of bonding pads and a protective layer, wherein the protective layer is used to protect the chip and exposes a surface of the bonding pads;
a wiring layer, covering a portion of the bonding pads and disposed on the protective layer;
a dielectric layer, wherein the dielectric layer is disposed over the protective layer and covering the wiring layer, the dielectric layer comprises a plurality of openings;
a conductive layer, wherein the conductive layer is at least formed over the openings;
a heat sink disposed on the dielectric layer; and
a plurality of bumps disposed on the conductive layer and over the bonding pads, wherein the bumps are to be connected to the contact points of the carrier when the wafer-level package structure is mounted on the carrier.

10. The structure of claim 9, wherein the chip further comprises a ground plane and the heat sink is electrically connected to the ground plane.

11. The structure of claim 10, wherein the openings are formed in the dielectric layer and at a periphery of the chip.

12. The structure of claim 11, wherein the heat sink is formed inside a region enclosed by the openings.

13. The structure of claim 9, wherein the bonding pads are formed with a material selected from the group consisting of copper and aluminum.

14. The structure of claim 9, wherein the conductive layer is formed with a material selected from the group consisting of aluminum/titanium tungsten alloy/nickel vanadium alloy/copper, chromium/nickel vanadium alloy/copper, aluminum/nickel vanadium alloy/copper and titanium/nickel vanadium alloy/copper.

15. The structure of claim 9, wherein the heat sink is formed with a material selected from the group consisting of aluminum/titanium tungsten alloy/nickel vanadium alloy/copper, chromium/nickel vanadium alloy/copper, aluminum/nickel vanadium alloy/copper and titanium/nickel vanadium alloy/copper.

16. The structure of claim 9, wherein the carrier includes a printed circuit board.

17. The structure of claim 9, wherein the conductive layer is disposed on and electrically connected to the bonding pads that are not covered by the wiring layer.

18. The structure of claim 9, wherein the conductive layer is disposed on the wiring layer and is electrically connected to the bonding pads that are covered by the wiring layer through the wiring layer.
